(19) United States
(12) Patent Application Publication
(10) Pub. No.: US 2025/0260554 A1
(43) Pub. Date: Aug. 14, 2025

(54) A TRANSMITTER AND A RECEIVER

(71) Applicant: DATA CONVERSION SYSTEMS LTD, Swavesey Cambridgeshire (GB)

(72) Inventors: Andrew Charles MCHARG, Swavesey, Cambridgeshire (GB); Richard James HOLLINSHEAD, Swavesey, Cambridgeshire (GB); Dammon George BUTLER, Swavesey, Cambridgeshire (GB)

(21) Appl. No.: 18/877,748

(22) PCT Filed: May 30, 2023
(86) PCT No.: PCT/GB2023/051418

§ 371 Date: Dec. 20, 2024

(30) Foreign Application Priority Data
Jun. 24, 2022 (GB) 2209260.5

(51) Int. Cl. H04L 7/04; H04L 7/00

(52) U.S. Cl. CPC H04L 7/043; H04L 7/0008

(57) ABSTRACT

The subject-matter of the present disclosure provides a transmitter for a master clock of an audio system. The transmitter comprises an input configured to receive a message to be sent to a receiver of an audio device of the audio system and clock frequency information of a clock signal for synchronising the audio device; a data stream generator configured to determine a data stream based on the message; a pulse shaper configured to generate an encoded clock signal in the form of a rectangular wave having an initiating edge timing based on the clock frequency and a terminating edge timing being earlier than or later than a half cycle of the encoded clock signal depending on a bit value of the data stream; and an output configured to transmit the encoded clock signal to the receiver.

### FIELD

The subject-matter of the present disclosure relates to a transmitter for a master clock of an audio system, and a receiver for an audio device of an audio system. More specifically, the transmitter and receiver are those able to transmit and receive a clock signal for synchronising audio devices within an audio system.

### BACKGROUND

Audio devices within an audio system need to be synchronised. Synchronisation may be achieved using clock signals. For example, in one method, a master clock may be employed to synchronise two or more audio devices within the audio system.

An audio device receiving a clock signal can monitor its pulses to replicate the clock signal. However, further information is required for the audio device to understanding the timing of the pulses. This is because latency across channels may mean that arbitrarily aligning rising edges to closest clock pulses would not necessarily match the correct pulses of clock signals between devices being synchronised.

Prior art methods have been attempted but often tie the audio device to using a particular data transmission method, e.g. Audio Engineering Society/European Broadcasting Union interfaces (AES/EBU) or Sony/Philips Digital Interface Format (SPDIF), etc.

The aim of the present disclosure is to alleviate such issues and improve on the prior art.

### SUMMARY

According to an aspect of the present disclosure, there is provided a transmitter for a master clock of an audio system. The transmitter comprises: an input configured to receive a message to be sent to a receiver of an audio device of the audio system and clock frequency information of a clock signal for synchronising the audio device; a data stream generator configured to determine a data stream based on the message; a pulse shaper configured to generate an encoded clock signal in the form of a rectangular wave having an initiating edge timing based on the clock frequency and a terminating edge timing being earlier than or later than a half cycle of the encoded clock signal depending on a bit value of the data stream; and an output configured to transmit the encoded clock signal to the receiver. In this way, the message may be encoded into the encoded clock signal so both the clock timing and the message can be transmitted simultaneously without need for a specific data transmission protocol.

In an embodiment, the transmitter may further comprised a pseudorandom number generator configured to generate a pseudorandom number key, wherein the data stream generator is configured to generate the data stream further based on the pseudorandom number key.

In an embodiment, the data stream may include a plurality of bits in the form of a frame, wherein the frame includes a synchronisation portion, followed by a trigger portion, followed by a message portion, the message portion corresponding to the received message and being m bits long, wherein the synchronisation portion is n plus s bits long, where n is a length of the pseudorandom number generator, and s is a number of bits for synchronising the receiver, and wherein the trigger portion is t bits long.

In an embodiment, s may be greater than m.

In an embodiment, the data stream generator may be configured to generate the data stream based on a payload of zeros and the pseudorandom number key during the synchronisation portion, based on a payload of one or more ones and the pseudorandom number key during the trigger portion, and based on a payload corresponding to the message and the pseudorandom number key during the message portion.

In an embodiment, the pseudorandom number generator may be a linear-feedback shift register.

In an embodiment, the transmitter may further comprise a pulse narrower configured to generate a first rectangular wave having a pulse width less than a half cycle of the encoded clock signal and may further comprise a pulse widener configured to generate a second rectangular wave having a pulse width greater than a half cycle of the encoded clock signal, wherein the pulse shaper may be configured to select the first or the second rectangular waves depending on a bit value of the data stream.

In an embodiment, the pulse widener and the pulse narrower may be configured to generate the first and second rectangular waves by combining pulses from a wave having a frequency that is a multiple of the encoded clock signal.

In an embodiment, the message may comprise a sample count or a time stamp.

In an embodiment, the initiating edge may be a rising edge and the terminating edge may be a falling edge.

According to an aspect of the present disclosure, there is provided a master clock device comprising the aforementioned transmitter.

According to an aspect of the present disclosure, there is provided a receiver for an audio device of an audio system, the receiver comprising: an input configured to receive an encoded clock signal from a transmitter for a master clock of the audio system; a clock signal generator configured to generate a square wave clock signal having a frequency based on a frequency of the encoded clock signal; and a data stream recoverer configured to obtain bit values of a data stream encoded within the encoded clock signal based on whether a terminating edge of the encoded clock signal is earlier than or later than a half cycle of the encoded clock signal, and to obtain a message based on the bit values of the data stream.

In an embodiment, the receiver may further comprise a pseudorandom number generator configured to generate a pseudorandom number key, wherein the data stream recoverer may be further configured to obtain the message based on bit values of the data stream and the pseudorandom number key.

In an embodiment, the data stream may include a plurality of bits in the form of a frame, wherein the frame includes a synchronisation portion, followed by a trigger portion, followed by a message portion, the message portion corresponding to the received message and being m bits long, wherein the synchronisation portion is n plus s bits long, where n is a length of the pseudorandom number generator, and s is a number of bits for synchronising the receiver, and wherein the trigger portion is t bits long.

In an embodiment, s may be greater than m.

In an embodiment, the receiver may further comprise a match counter configured to reset the pseudorandom number generator in response to detecting the trigger portion, and may be configured to output the message in response to counting m bits after the trigger portion.

In an embodiment, the pseudorandom number generator may be a linear-feedback shift register.

In an embodiment, the receiver may further comprise a pulse width detector configured to determine whether a terminating edge of the encoded clock signal is earlier than or later than a half cycle of the encoded clock signal by sampling the encoded clock signal at a frequency being a multiple of the frequency of the wave used to generate the encoded clock signal pulses.

In an embodiment, the message may further comprise a sample count or a time stamp.

In an embodiment, the clock signal generator may be configured to generate the square wave clock signal by dividing the frequency of the encoded clock signal by two.

In an embodiment, the initiating edge may be a rising edge and the terminating edge may be a falling edge.

According to an aspect of the present disclosure, there is provided an audio device comprising the aforementioned receiver.

According to an aspect of the present disclosure, there is provided a system comprising the aforementioned transmitter, and the aforementioned receiver.

According to an aspect of the present disclosure, there is provided an audio system comprises the aforementioned master clock device and the aforementioned audio device. According to an aspect of the present disclosure, there is provided a method of encoding an encoded clock signal, the method comprising: receiving a message to be sent to a receiver of an audio device of the audio system and clock frequency information of a clock signal for synchronising the audio device; determining a data stream based on the message; generating an encoded clock signal in the form of a rectangular wave having an initiating edge timing based on the clock frequency and a terminating edge timing being earlier than or later than a half cycle of the encoded clock signal depending on a bit value of the data stream; and transmitting the encoded clock signal to the receiver.

In an embodiment, the initiating edge may be a rising edge and the terminating edge may be a falling edge.

According to an aspect of the present disclosure, there is provided a method of obtaining a message and a clock signal from an encoded clock signal, the method comprising: receiving an encoded clock signal from a transmitter for a master clock of an audio system; generating a square wave clock signal having a frequency based on the frequency of the encoded clock signal; obtaining bit values of a data stream encoded within the encoded clock signal based on whether a terminating edge of the encoded clock signal is earlier than or later than a half cycle of the encoded clock signal; and obtaining a message based on bit values of the data stream.

In an embodiment, the terminating edge may be a falling edge.

According to a further aspect of the present disclosure, there is provided a transitory, or non-transitory, computer readable medium, having instructions stored thereon that when executed by a processor, cause the processor to perform either of the foregoing methods.

### BRIEF DESCRIPTION OF DRAWINGS

The subject-matter of the present disclosure is best described with reference to the accompanying figures, in which:

FIG. 1 shows a block diagram of a system (an audio system) according to one or more embodiments;

FIG. 2 shows a block diagram of a transmitter from a clock source shown in FIG. 1, according to one or more embodiments;

FIG. 3 shows a block diagram of a data stream generator from the transmitter from FIG. 2, according to an embodiment;

FIG. 4 shows an encoded clock signal generated by the transmitter of FIG. 2, and a recovered clock signal generated by a receiver (FIG. 6);

FIG. 5 shows a block diagram of another transmitter than the transmitter shown in FIG. 2, according to one or more embodiments;

FIG. 6 shows a block diagram of a receiver from the audio device shown in FIG. 1;

FIG. 7 shows a block diagram of a data stream recoverer from the receiver of FIG. 6;

FIG. 8 shows a flow diagram of a method of encoding an encoded clock signal according to one or more embodiments; and

FIG. 9 shows a flow diagram of a method of obtaining a message and a clock signal from an encoded clock signal.

### DESCRIPTION OF EMBODIMENTS

It will be appreciated that whilst various features are described herein with reference to one or more embodiments, features from different embodiments may be included in other embodiments without constituting an addition of subject-matter extending beyond the content of what is described herein.

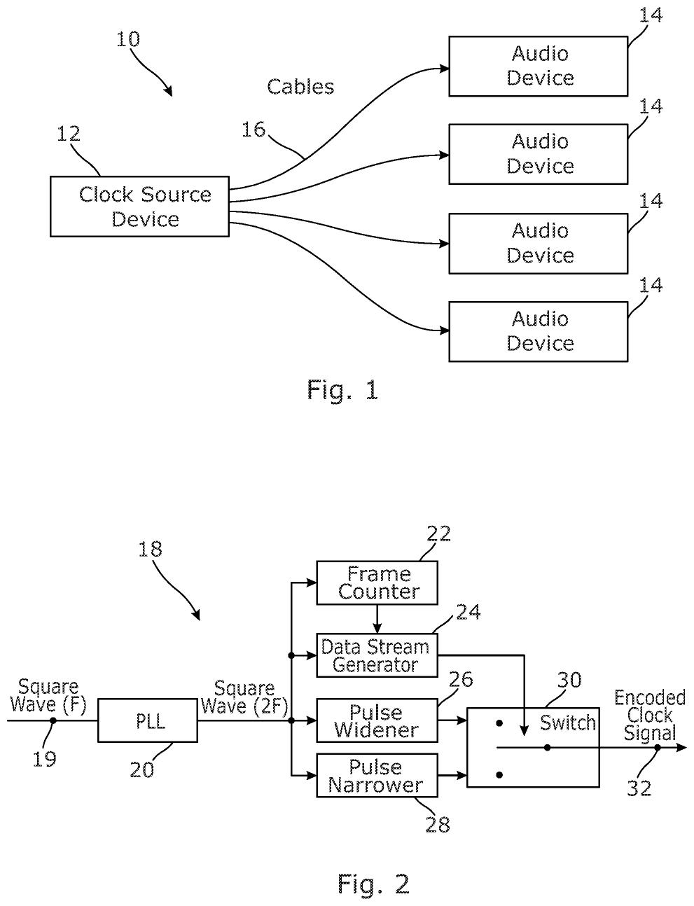

With reference to FIG. 1, there is provided an audio system 10. The audio system 10 includes a clock source device 12, otherwise known as a master clock or a clock box, and one or more audio device 14. The one or more audio devices may be devices suitable for producing audio. Examples of audio devices include a transport, (e.g. a compact disc reader, or an MP3 player), a digital-to-analogue converter (DAC), an up-sampler, a headphone amplifier, and a user interface. Sound producing devices including one or more speakers, headphones, etc. may be connected to the one or more audio devices to produce sound provided on the transport.

The clock box 12 may be connected to each audio device using a cable.

The clock box 12 includes a transmitter 18 which is shown in FIG. 2.

With reference to FIG. 2, the transmitter 18 includes an input 19, a clock signal generator 20, a frame counter 22, a data stream generator 24, a pulse widener 26, a pulse narrower 28, a pulse shaper 30, and an output 32.

The input 19 is configured to receive a clock signal. The clock signal is a square wave. The input square wave has a frequency f (where f may be used interchangeably herein with F to denote frequency) that is intended to be used to synchronise the audio devices 14 (FIG. 1). In this way, the input is configured to receive clock frequency information of a clock signal for synchronising the audio devices 14, since the information relating to the clock frequency is derivable from the square wave itself.

The clock signal generator 20 obtains the input square wave from the input 19. The clock signal generator 20 is configured to generate a modified square wave based on the input square wave. The clock signal generator 20 may be provided in the form of a phase lock loop (PLL). The phase lock loop generates the modified square wave by doubling the frequency of the input square wave. In this way, the modified square wave has a frequency of 2f (or 2F).

The modified square wave is then used as an input to the frame counter 22 (or counter), the data stream generator 24, the pulse widener 26, and the pulse narrower 28.

The frame counter 22 is aware of a number of bits in a frame. The frame counter 22 may obtain the number of bits of the frame from a memory (not shown) of the clock source. The frame counter 22 is configured to count the number of pulses in the modified square wave within a frame and generate a restart condition when the data stream generator 24 needs to re-start producing another frame's worth of bits.

A frame is a number of bits required to send a message to the audio devices. The frame includes a synchronisation portion, followed by a trigger portion, followed by a message portion, the message portion corresponding to the received message. The message portion may be m bits long. The synchronisation portion is n plus s bits long, where n is a length of the pseudorandom number generator (see below), and s is a number of bits for synchronising the receiver. The trigger portion is t bits long.

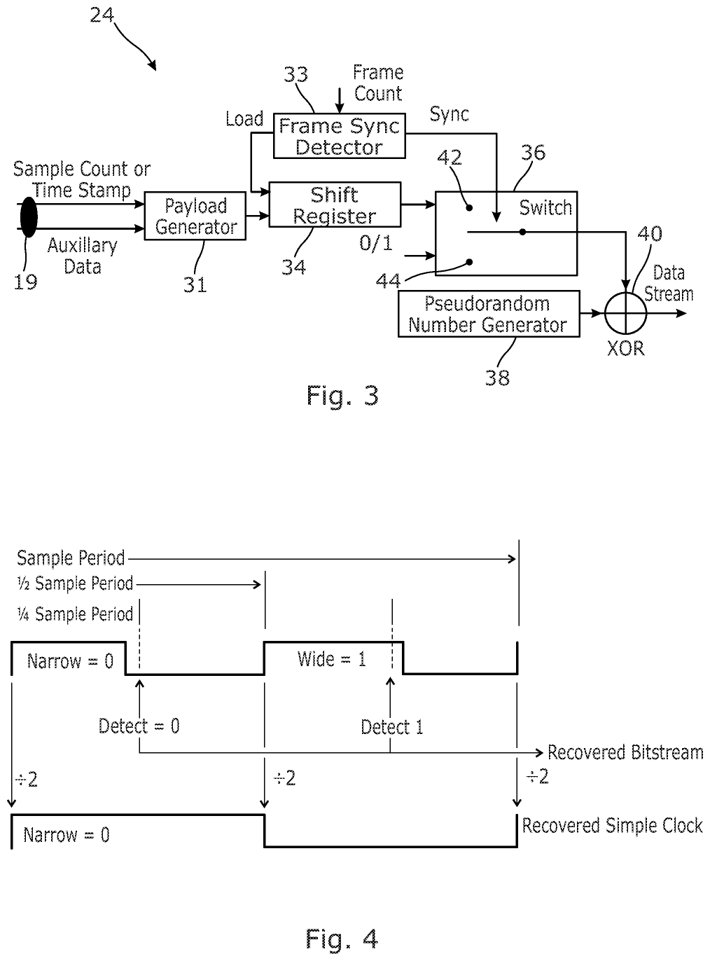

With reference to FIG. 3, the data stream generator 24 is connected to the input 19. The data stream generator 24 is configured to generate a data stream based on, at least in part, the message. In other words, the data stream generator 24 is configured to generate a data stream describing the message in binary form.

To achieve this, the data stream generator 24 includes a payload generator 31, a frame synchronisation detector 33, a shift-register 34, a switch 36, a pseudorandom number generator 38, and a data stream combiner 40. It should be noted that each of the payload generator 31, the frame synchronisation detector 32, the shift-register 34, the switch 36, and the pseudorandom number generator 38, have the modified square wave 2F as an input, and this has not been included in FIG. 3 for the sake of brevity and to aid clarity of the figures.

The input 19 also receives a message to be sent to the respective receivers of the audio devices 14. The message may be in the form of a sample count or time stamp, or even auxiliary data. The input 19 may be the same input as shown in FIG. 2, or a different input. The sample count may indicate a sequence order of samples of data packets containing the audio samples. The time stamp may be a time according to the clock box 12. In practice, it will likely be one or the other of the time stamp and sample count that will be sent. The sample count and time stamp will be used by the audio device so the audio device has knowledge of which frame is being received. The auxiliary data may be any other data that may be transmitter as a message to an audio device. For example, the name of the clock box, its part number or serial number, or technical specifications may be transmitted. The auxiliary data may be transmitted alternately with the sample count or time stamp.

The payload generator 31 is configured to receive the message and generate a payload in response. The payload may include the message in binary form. As described elsewhere in this disclosure, the payload may also be used to describe all binary values within a frame. In this way, the payload generator 31 may be called a payload message portion generator.

The shift-register 34 is configured to convert the payload into serial data. In this way, the payload may be a bit stream. The shift-register 34 also receives a signal from the frame synchronisation detector 33 regarding when to output the bit stream. The signal may be called a load signal Load. The Load signal is sent once the Frame synchronisation detector 33 counts a number of bits of the frame signifying an end of the message.

The frame synchronisation detector 33 is configured to receive a frame count signal Frame Count from the frame counter 22 (FIG. 2). The frame count signal indicates to the frame synchronisation detector when the frame counter 22 has counted all bits of a frame, so the frame count signal acts as a reset for the frame synchronisation detector 33 to start counting again.

The frame synchronisation detector 33 is also configured to output a synchronisation signal Sync to the switch 36. The switch has two inputs. The first input 42 is the output of the shift register 34, namely the bitstream describing the message. The second input 44 is also a bit stream, and can also be termed a pay load. The payload generator 31 may generate this additional bit stream or this additional bit stream may be generated by a different source. This additional payload may include two sub payloads, namely a synchronisation payload and a trigger payload.

To avoid confusion, the inputs globally to the switch 36 may be considered a payload. The payload may include a plurality of portions, each corresponding to a portion of the frame. The payload may include a message portion (output from the shift register 34), and is input to the first input 42. There may be m bits of binary values (0 or 1) in the message portion. The number of bits m is selected to be sufficient to define the message using binary notation. The payload may also include a synchronisation portion input to the second input 44. The synchronisation portion may include n plus s bits of binary values. The n and s binary value may all be zeros. The number of bits n may be the length of the pseudorandom key produced by the pseudorandom number generator 38 (see below). The number of bits s, may be more than the number of bits m. The reason for this will be best understood with reference to the receiver (see below). However, in summary, it is theoretically possible that the message payload comprises large sections with solely zeros, with no ones. If the message portion were greater than the synchronisation portion, false resets of the pseudorandom number generator may occur in such cases. The payload may also include a tigger portion having t bits. The trigger portion may be input to the second input 44. The number of bits t may be a single bit in length and may have a value of 1.

When the frame synchronisation detector 33 receives the frame count signal Frame Count, and resets, it is configured to send the synchronisation signal Sync to the switch 36. The synchronisation signal Sync is configured to switch the switch to the second input 44. In this way, the synchronisation portion and the trigger portion of the payload are output to the data stream combiner 40 when the synchronisation signal Sync is active. When the frame synchronisation detector 33 has counted n plus s plus t bits, the synchronisation signal Sync ends. Without the synchronisation signal Sync, the switch defaults to the first input 42. When the first input 42 is selected, the shift register 34 outputs the message portion of the payload to the data stream combiner 40.

In some embodiments n may be 24 bits long, m may be 60 bits long, s may be 61 bits long, and t may be 1 bit long. In this way, a frame may be 146 bits long.

The pseudorandom number generator 38 is configured to generate a pseudorandom number key (or pseudorandom key). A suitable pseudorandom number generator 38 will successively progress through all of the n-bit numbers. Numbers are unique in the sense that they only recur after all other possible numbers have been exhausted.

To achieve this, the pseudorandom number generator 38 may include a linear feedback shift-register, LFSR. LFSRs are able to achieve a unique set of numbers except for zero.

If the series of n-bit numbers is considered as a bit stream (without word boundaries) a LFSR produces unique numbers at any point in the bitstream. There may be other types of pseudorandom number generators 38 that share this characteristic. Therefore, use of an LFSR is not necessary provided that the pseudorandom number generator 38 is able to function in this way. For the purposes of the embodiments described herein, the pseudorandom number generator 38 may a LFSR for illustrative purposes.

The LFSR may be 24 bits long. In this way, the pseudorandom key will include 24 bits of ones and zeros that appear in a random sequence, although their order will be dictated by the construction of the LFSR.

Whilst not shown in FIG. 3 for brevity, the synchronisation signal Sync is also available for the LFSR. In this way, once the trigger portion has been sent, the pseudorandom number generator restarts generating the pseudorandom key. Therefore, the pseudorandom number generator 38 is configured to generate a pseudorandom key of 24 bits once during the first n bits, then two keys of 24 bits during s before resetting during a third key. The end of the third key coincides with the trigger bit t. Then the pseudorandom number generator 38 generates two and a bit pseudorandom keys when the load signal Load is active and the synchronisation signal Sync is inactive.

The data stream combiner 40 is configured to combine the payload and the pseudorandom key. For instance, data stream combiner 40 may be an exclusive OR gate, XOR. The output from the data stream combiner 40 may be a data stream. In other words, the data stream generator is configured to generate the data stream based on the pseudorandom key. It will be appreciated that during the synchronisation portion, when the payload is zeros, the data stream will be the pseudorandom key. During the trigger portion, the data stream will be the opposite value to the pseudorandom key. During the message portion, the message will appear to be encoded and will very unlikely match the pseudorandom key over all 60 bits. It should also be noted that the message portion is shorter than the synchronization portion, thus avoiding false syncs. If the message happens to be, or end in, lots of consecutive zeros, a sync is still detected at the trigger bit.

In this way, the data stream generator 24 is configured to generate the data stream based on a payload of zeros and the pseudorandom number key during the synchronisation portion, based on a payload of one or more ones and the pseudorandom number key during the trigger portion, and based on a payload corresponding to the message and the pseudorandom number key during the message portion.

With reference again to FIG. 2, the switch uses the data stream as a switch signal.

The pulse widener 26 and the pulse narrower 28 have the modified clock signal, or modified square wave, as an input. While not shown in FIG. 2 for brevity, a further input to the pulse widener 26 and the pulse narrower 28 is a fast clock. The fast clock may have a frequency of a multiple of the modified clock. For example, the square wave to synchronise the audio devices may have a frequency of 48 KHz. The square wave frequency may correspond to the sample rate of the audio signal(s). The modified clock signal may have a frequency of 96 KHz. The high clock frequency may have a frequency of a multiple, e.g. 32 times, that of the modified clock signal. The high clock frequency may be around 3.1 MHz (to two significant figures).

With reference to FIGS. 2 and 4, the pulse widener 26 may be configured to use pulses from the high clock frequency to construct the modified clock signal. For instance, the modified clock signal, if it were to be a direct doubling of the clock signal frequency f, may be a frequency 2f, or 2F. Therefore, it is possible to construct a narrow pulse using 15/32 pulses from the fast clock. It is possible to construct the wide pulse using 17/32 pulses from the fast clock. In this way, the pulse widener 26 and the pulse narrower 28 are configured to generate the first and second rectangular waves by combining pulses from a wave having a frequency that is a multiple of the encoded clock signal. As a result, falling edge of the narrow pulse is earlier than a ½ cycle of the modified clock signal and falling edge of the wide pulse is later than a ½ cycle of the modified clock signal.

The output from the pulse widener 26 may be a first rectangular wave having a pulse width less than a half cycle of the encoded clock signal. The output from the pulse narrower 28 may be a second rectangular wave having a pulse width greater than a half cycle of the encoded clock signal. The pulse shaper 30 is configured to generate an encoded clock signal in the form of a rectangular wave having an initiating edge whose timing is based on the clock frequency information and a terminating edge being earlier than or later than a half cycle of the encoded clock signal depending on a bit value of the data stream. The term “initiating edge” and the term “terminating edge” may be defined more specifically, in some embodiments, respectively as “a rising edge” and a “falling edge”. More specifically, the pulse shaper 30 may be configured to select the first or the second rectangular waves depending on a bit value of the data stream. To achieve this, the pulse shaper 30 may be in the form of a switch. For instance, when the bit value is a one, the pulse shaper 30 may select the output of the pulse widener 26, namely the first rectangular wave. When the bit value is a zero, the pulse shaper 30 may select the output of the pulse narrower, namely the second rectangular wave. In this way, the modified clock signal will have a value of one, or high, at a ½ cycle of the encoded clock signal when the bit value from the data stream is a one. The modified clock signal will have a value of zero, or low, at a ½ cycle of the encoded clock signal when a bit value from the data stream is a zero.

The output from the pulse shaper 30 is the encoded clock signal. The output 32 is configured to transmit the encoded clock signal to a receiver.

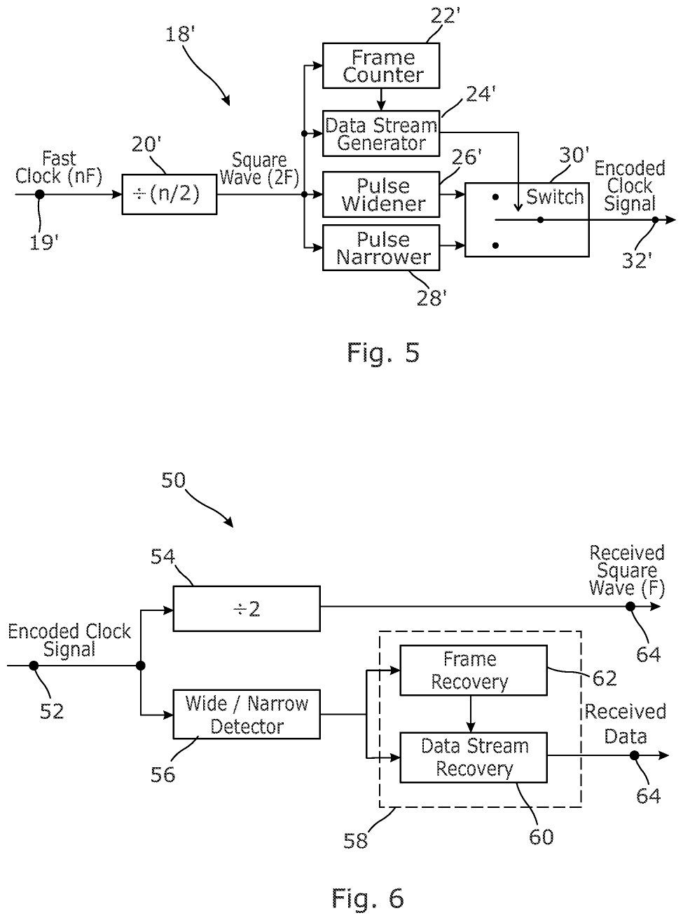

With reference to FIG. 5, a further embodiment of a transmitter 18′ is provided. The reference numerals used for this embodiment are the same as those that have been used for the embodiment from FIG. 2 and appended with a prime (′). The following description explains the differences between the embodiment of FIG. 5 and that of FIG. 2. All other features may be considered the same.

The input 19′ is configured to receive a fast clock. The fast clock (nf or nF) may have a frequency of a multiple of the clock signal that is used for synchronising the audio devices. For example, the square wave to synchronise the audio devices may have a frequency of 48 KHz. The modified clock signal may have a frequency of 96 KHz. The high clock frequency may have a frequency of a multiple, e.g. 32 times, that of the modified clock signal. The high clock frequency may be around 3.1 MHz (to two significant figures). In addition to the fast clock, the transmitter 18′ may receive a clock frequency of the clock signal that will be used to synchronise the audio devices. The clock frequency can be provided in the form of clock frequency information.

In FIG. 5, “n” may be a power of 2 (e.g. 2, 4, 8, 16, 32, etc.). Whilst “n” may be variable, in practice, it may have a fixed value. In other words, the clock frequency information may be stored in a database and may not be variable, i.e. it may be predetermined and may be fixed. Alternatively, the flock frequency information may be embodied in the circuit of the hardware.

The clock signal generator 20′ is configured to generate a modified square wave (2F) based on the fast clock (nF). The clock signal generator 20′ may comprise one or more flip flops. In this way, the modified clock signal has a frequency of 2f (or 2F). The modified clock signal is input to the frame counter 22′, the data stream generator 24′, the pulse widener 26′, and the pulse narrower 28′, each of which work in the same way as the embodiment from FIG. 2.

With reference to FIG. 6, each audio device 14 (FIG. 1) includes a receiver 50.

The receiver 50 includes an input 52, a clock signal generator 54, a pulse width detector 56, a data stream recoverer 58, and an output 64. The data stream recoverer 58 includes a frame recovery means 62 and a data stream recovery means 60.

The input 52 may be configured to receive the encoded clock signal from the transmitter 18.

The clock signal generator 54 may be in the form of a counter. The counter may be a division counter. The division counter may divide the encoded clock signal, having a frequency of 2f, by two, to generate a clock signal having a frequency of f. The clock signal may thus be a square wave, rather than the rectangular wave of the encoded clock signal. The square wave may then be output from the output 64 to a processor of the audio device 14 for synchronisation with other audio devices 14. In other words, the clock signal generator 54 may be configured to generate a square wave clock signal having a frequency based on a frequency of the encoded clock signal.

The pulse width detector 56 may be a wide and narrow detector. The pulse width detector 56 may be configured to determine whether a falling edge of the encoded clock signal is earlier than or later than a half cycle of the encoded clock signal by sampling the encoded clock signal at a frequency being a multiple of the frequency of the wave used to generate the encoded clock signal pulses. For example, the fast clock has been used to generate the encoded clock signal pulses by the transmitter. The frequency used to monitor the timing of the falling edge may be a multiple of the fast clock. The frequency used to monitor the timing of the falling edge may be double the frequency of the fast clock, for example, 6.1 MHz (to two significant figures). In this way, if the value of the encoded clock signal is high, or one, at 32/64 pulses, a wide pulse is detected. If the value of the encoded clock signal is low, or zero, at 32/64 pulses, a narrow pulse is detected. The output from the pulse width detector 56 may be a bit stream of ones and zeros corresponding respectively to wide and narrow pulses. Alternatively, the same resolution may be used to monitor the timing of the falling edge in other embodiments. For example, if wide and narrow pulses are respectively 15 and 17 fast clock cycles wide, it is possible to test at 16 cycles.

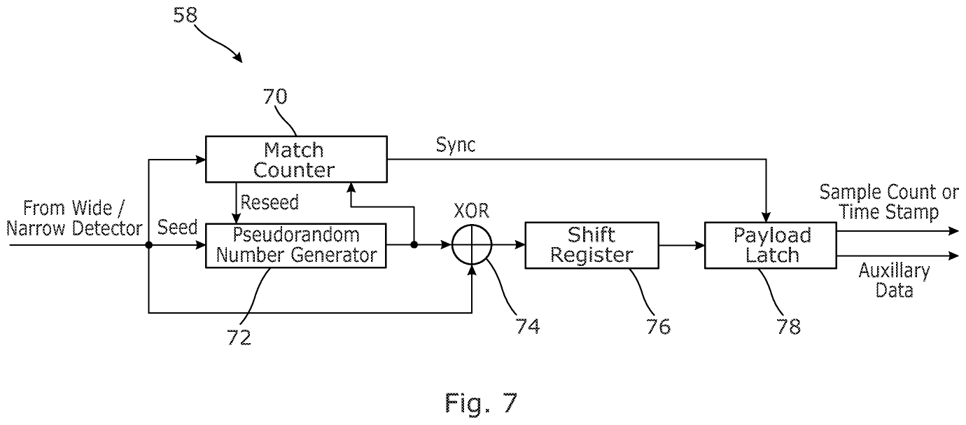

The data stream recoverer 58 is configured to receive the bit stream from the pulse width detector 56. Whilst operation of the data stream recoverer 58 may be understood best with reference to FIG. 7, in summary, the data stream recoverer 58 is configured to obtain bit values of a data stream encoded within the encoded clock signal based on whether a falling edge of the encoded clock signal is earlier than or later than a half cycle of the encoded clock signal. In addition, the data stream recoverer 58 may be configured to obtain a message based on the bit values of the data stream.

With reference to FIG. 7, the data stream recoverer 58 includes a match counter 70, a pseudorandom number generator 72, a combiner 74, a shift register 76, and a payload latch 78. Broadly speaking, the match counter 70 corresponds to the frame recovery means 62 from FIG. 6, and the pseudorandom number generator 72, the combiner 74, the shift register 76, and the payload latch 78, correspond to the data stream recovery means 70 from FIG. 6.

The match counter 70 (or counter) is configured to count the number of bits in the bit stream. The match counter 70 is configured to count the number of bits of a frame, namely 146 bits. The match counter 70 has two inputs, namely the bit stream from the pulse width detector and an output from the pseudorandom number generator 72. The match counter 70 has two outputs, one is a reseed signal Reseed and a synchronisation signal Sync. The match counter 70 is configured to compare the bit values from the bit stream with those from the pseudorandom key. In response to a mismatch, the reseed signal Reseed is sent to the pseudorandom number generator. It will be appreciated that the bit stream will match the pseudorandom key for 64 bits, namely for message parts n and m, since zeros are used for the payload for those portions of the frame. When the trigger bit t is compared, there will be a mismatch because the payload for t is one. Therefore, the “exclusive or” combination of the trigger bit (one) and the pseudorandom key value will not have the same value as the pseudorandom key. The reseed signal Reseed is then suspended for 60 bits. The other output, the synchronisation signal Sync, is output on the final bit (60^{th} bit after the reseed signal has been output) of the frame to the payload latch 78.

Once the entire frame has been decoded, encoding restarts with a subsequent frame.

The pseudorandom number generator 72 receives the bit stream output by the pulse width detector. The first bit of the frame is considered a seed signal Seed. In response to the seed signal Seed, the pseudorandom number generator 72 generates the pseudorandom key. The pseudorandom number generator 72 may include a linear-feedback shift-register (LFSR). The LFSR may be 24 bits long. The LFSR may be identical to the LFSR in the transmitter. In this way, the pseudorandom number generator 72 will generator the same pseudorandom key as in the transmitter. The pseudorandom number generator 72 repeatedly generates a pseudorandom key of 24 bits long until it receives the reseed signal Reseed, at which point it resets and starts generating the pseudorandom key from bit one again. In this way, the match counter is configured to reset the pseudorandom number generator in response to detecting the trigger portion. The pseudorandom key is output to the combiner 74 and the match counter 70.

The combiner 74 receives two inputs. The first input is the pseudorandom key. The second input is the bit stream output from the pulse width detector. The first and second inputs are combined by the combiner 74. The combiner 74 may be provided in the form of an exclusive or gate. A combined bitstream is output from the combiner 74 to the shift register 76.

In this way, the data stream recoverer is further configured to obtain the message based on bit values of the data stream and the pseudorandom number key.

In response to receiving the synchronisation signal Sync, the payload latch 78 is configured to latch the latest 60 bits in the shift register. The latest 60 bits correspond to bits m of the frame, which correspond to the message. In this way, the match counter 70 is configured to output the message in response to counting m bits after the trigger portion.

The message may be a time stamp or a sample count. The output from the payload latch 78 may be the sample count or the time stamp. In this way, the payload latch may also be called a message latch.

With reference reference to FIG. 6, the output 64 is configured to output the decoded message (time stamp or sample count) to a processor of the audio device 14 (FIG. 1) so that the audio device is able to synchronise the clock signal with other devices.

The various features of the transmitter and receiver described in the foregoing embodiments may be embodied as instructions stored on a computer readable medium. The instructions may be executable by a processor to cause the processor to perform the functions described herein.

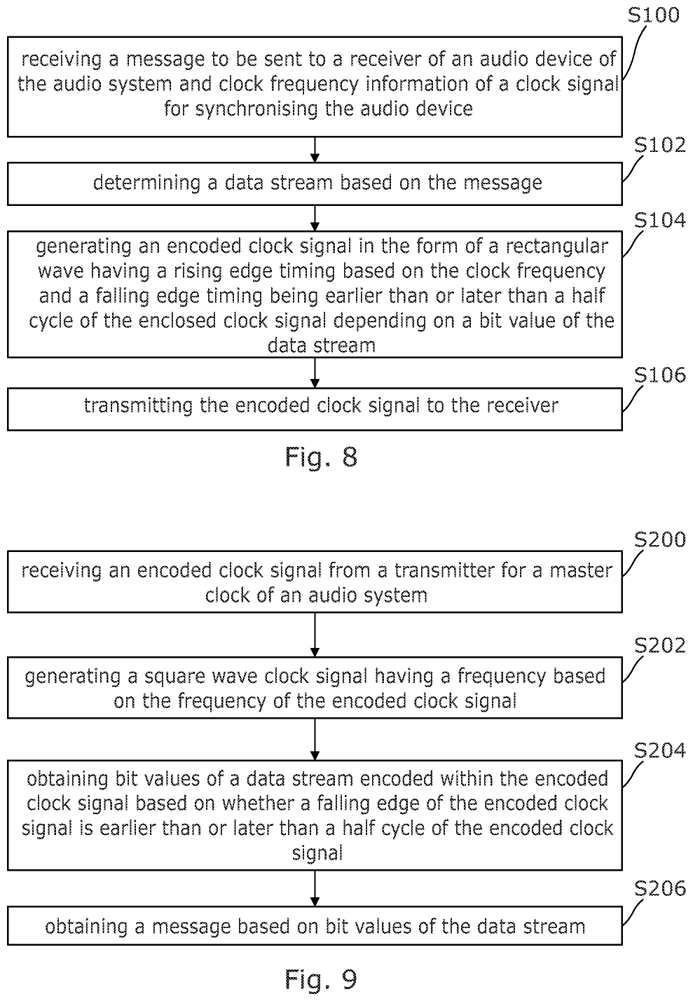

With reference to FIG. 8, the various features of the transmitter may be understood as method steps. The method may be a method of encoding an encoded clock signal. In addition to the other details included above, the method comprises: receiving, at step S100, a message to be sent to a receiver of an audio device of the audio system and clock frequency information of a clock signal for synchronising the audio device; determining, at step S102, a data stream based on the message; generating, at step S104, an encoded clock signal in the form of a rectangular wave having a rising edge timing based on the clock frequency and a falling edge timing being earlier than or later than a half cycle of the encoded clock signal depending on a bit value of the data stream; and transmitting, at step S106, the encoded clock signal to the receiver.

With reference to FIG. 9, the various features of the receiver may be understood as method steps. The method may be a method of obtaining a message and a clock signal from an encoded clock signal. The method comprises: receiving, at step S200, an encoded clock signal from a transmitter for a master clock of an audio system; generating, at step S202, a square wave clock signal having a frequency based on the frequency of the encoded clock signal; obtaining, at step S204, bit values of a data stream encoded within the encoded clock signal based on whether a falling edge of the encoded clock signal is earlier than or later than a half cycle of the encoded clock signal; and obtaining, at step S206, a message based on bit values of the data stream.

1. A transmitter for a master clock of an audio system, the transmitter comprising:
an input configured to receive a message to be sent to a receiver of an audio device of the audio system and clock frequency information of a clock signal for synchronising the audio device;
a data stream generator configured to determine a data stream based on the message;
a pulse shaper configured to generate an encoded clock signal in the form of a rectangular wave having an initiating signal edge timing based on the clock frequency and a terminating signal edge timing being earlier than or later than a half cycle of the encoded clock signal depending on a bit value of the data stream; and
an output configured to transmit the encoded clock signal to the receiver.

2. The transmitter of claim 1, further comprising a pseudorandom number generator configured to generate a pseudorandom number key, wherein the data stream generator is configured to generate the data stream further based on the pseudorandom number key.

3. The transmitter of claim 2, wherein data stream includes a plurality of bits in the form of a frame, wherein the frame includes a synchronisation portion, followed by a trigger portion, followed by a message portion, the message portion corresponding to the received message and being m bits long, wherein the synchronisation portion is n plus s bits long, where n is a length of the pseudorandom number generator, and s is a number of bits for synchronising the receiver, and wherein the trigger portion is t bits long.

4. The transmitter of claim 3, wherein s is greater than m.

5. The transmitter of claim 3 or claim 4, wherein the data stream generator is configured to generate the data stream based on a payload of zeros and the pseudorandom number key during the synchronisation portion, based on a payload of one or more ones and the pseudorandom number key during the trigger portion, and based on a payload corresponding to the message and the pseudorandom number key during the message portion.

6. The transmitter of claim 2, wherein the pseudorandom number generator is a linear-feedback shift register.

7. The transmitter of claim 1, further comprising a pulse narrower configured to generate a first rectangular wave having a pulse width less than a half cycle of the encoded clock signal and further comprising a pulse widener configured to generate a second rectangular wave having a pulse width greater than a half cycle of the encoded clock signal, wherein the pulse shaper is configured to select the first or the second rectangular waves depending on a bit value of the data stream.

8. The transmitter of claim 7 wherein the pulse widener and the pulse narrower are configured to generate the first and second rectangular waves by combining pulses from a wave having a frequency that is a multiple of the encoded clock signal.

9. The transmitter of claim 1, wherein the message comprises a sample count or a time stamp.

10. (canceled)

11. A receiver for an audio device of an audio system, the receiver comprising:
an input configured to receive an encoded clock signal from a transmitter for a master clock of the audio system;
a clock signal generator configured to generate a square wave clock signal having a frequency based on a frequency of the encoded clock signal; and
a data stream recoverer configured to obtain bit values of a data stream encoded within the encoded clock signal based on whether a terminating signal edge of the encoded clock signal is earlier than or later than a half cycle of the encoded clock signal, and to obtain a message based on the bit values of the data stream.

12. The receiver of claim 11, further comprising a pseudorandom number generator configured to generate a pseudorandom number key, wherein the data stream recoverer is further configured to obtain the message based on bit values of the data stream and the pseudorandom number key.

13. The receiver of claim 12, wherein data stream includes a plurality of bits in the form of a frame, wherein the frame includes a synchronisation portion, followed by a trigger portion, followed by a message portion, the message portion corresponding to the received message and being m bits long, wherein the synchronisation portion is n plus s bits long, where n is a length of the pseudorandom number generator, and s is a number of bits for synchronising the receiver, and wherein the trigger portion is t bits long.

14. The receiver of claim 13, wherein s is greater than m.

15. The receiver of claim 13, further comprising a match counter configured to reset the pseudorandom number generator in response to detecting the trigger portion, and configured to output the message in response to counting m bits after the trigger portion.

16. The receiver of claim 12, wherein the pseudorandom number generator is a linear-feedback shift register.

17. The receiver of claim 11, further comprising a pulse width detector configured to determine whether a terminating signal edge of the encoded clock signal is earlier than or later than a half cycle of the encoded clock signal by sampling the encoded clock signal at a frequency being a multiple of the frequency of the wave used to generate the encoded clock signal pulses.

18. The receiver of claim 11, wherein the message comprises a sample count or a time stamp.

19. The receiver of claim 11, wherein the clock signal generator is configured to generate the square wave clock signal by dividing the frequency of the encoded clock signal by two.

20-23. (canceled)
